(19) United States
(12) Patent Application Publication
(10) Pub. No.: US 2011/0020546 A1
(43) Pub. Date: Jan. 27, 2011

(54) Low Temperature ALD of Noble Metals

(75) Inventors: Jani Hämäläinen, Espoo (FI); Mikko Ritala, Espoo (FI); Markku Leskelä, Espoo (FI)

Correspondence Address: Knobbe, Martens, Olson & Bear LLP, 2040 Main Street, 14th Floor, Irvine, CA, 92614, US

(73) Assignee: ASM INTERNATIONAL N.V., Almere (NL)

(21) Appl. No.: 12/778,411

(22) Filed: May 12, 2010

Related U.S. Application Data
(60) Provisional application No. 61/178,841, filed on May 15, 2009.

(51) Int. Cl. C23C 16/515

(52) U.S. Cl. 427/250

(57) ABSTRACT

Noble metal films can be deposited by atomic layer deposition (ALD)-type processes. In preferred embodiments, Ir, Pd, and Pt are deposited by alternately and sequentially contacting a substrate with vapor phase pulses of a noble metal precursor, an oxygen source, and a hydrogen source. The oxygen source is preferably a reactive oxygen species. Preferably the deposition temperature is less than about 200° C. Preferably, pulses of the hydrogen source are less than 10 seconds.

### CROSS-REFERENCE TO RELATED APPLICATIONS

The present application claims priority under 35 U.S.C. §119(e) to U.S. Provisional Application Ser. No. 61/178,841 filed May 15, 2009, entitled LOW TEMPERATURE ALD OF NOBLE METALS, which is hereby incorporated by reference in its entirety.

### PARTIES OF JOINT RESEARCH AGREEMENT

The invention claimed herein was made by, or on behalf of, and/or in connection with a joint research agreement between the University of Helsinki and ASM Microchemistry signed on Nov. 14, 2003. The agreement was in effect on and before the date the claimed invention was made, and the claimed invention was made as a result of activities undertaken within the scope of the agreement.

### BACKGROUND OF THE INVENTION

1. Field of the Invention

The present invention relates generally to processes for producing noble metal thin films on a substrate by atomic layer deposition.

2. Description of the Related Art

ALD is a process based on self-limiting reactants, whereby alternated pulses of reaction precursors saturate a substrate surface and generally leave no more than about one monolayer of material per pulse. The deposition conditions and precursors are selected to provide self-saturating reactions, such that an adsorbed layer in one pulse leaves a surface termination that is non-reactive with the gas phase reactants of the same pulse. A subsequent pulse of different reactants reacts with the previous termination to enable continued deposition. Thus, each cycle of alternated pulses generally leaves no more than about one molecular layer of the desired material. The principles of ALD type processes have been presented by T. Suntola, e.g. in the Handbook of Crystal Growth 3, Thin Films and Epitaxy, Part B: Growth Mechanisms and Dynamics, Chapter 14, Atomic Layer Epitaxy, pp. 601-663, Elsevier Science B.V. 1994, the disclosure of which is incorporated herein by reference. Variations of ALD have been proposed that allow for modulation of the growth rate. However, to provide for high conformality and thickness uniformity, these reactions are still more or less self-saturating.

### SUMMARY OF THE INVENTION

In accordance with one aspect of the present invention, methods of depositing a noble metal film on a substrate in a reaction chamber by atomic layer deposition are provided. In some embodiments, the method comprises: conducting a plurality of ALD cycles, each of the cycles forming less than a complete monolayer of noble metal oxide, each of the cycles comprising: exposing the substrate to a pulse of a noble metal precursor to leave an adsorbed layer of the noble metal precursor, exposing the adsorbed layer of the noble metal precursor to a pulse of a reactive oxygen species to produce a noble metal oxide, and wherein the noble metal oxide is exposed to a pulse of H₂ in the same chamber at the same temperature to reduce the noble metal oxide to noble metal, wherein the substrate temperature during the ALD cycle is less than about 200° C.

In accordance with another aspect of the present invention, atomic layer deposition (ALD) processes for forming a noble metal thin film are provided. In some embodiments, the method comprises alternately and sequentially contacting a substrate, in order, with a noble metal precursor, a reactive oxygen source, and a hydrogen source, wherein the substrate temperature during deposition is less than about 200° C., wherein contacting the substrate with a hydrogen source comprises a pulse with a duration of 10 seconds or less.

### BRIEF DESCRIPTION OF THE DRAWINGS

FIG. 1 is a flow chart generally illustrating a method for forming a noble metal film in accordance with one embodiment.

FIG. 2 is an x-ray diffractogram (XRD) of iridium films deposited by ALD at various deposition temperatures;

FIG. 3 is a graph illustrating the growth rate of iridium films formed by ALD at various deposition temperatures;

FIG. 4 is a graph illustrating the growth rate and resistivities of iridium films formed by ALD on in-situ grown Al₂O₃ on top of various substrates and with varying hydrogen pulse lengths;

FIG. 5 is a graph illustrating the film thickness versus number of deposition cycles for Iridium films formed on in-situ grown Al₂O₃ on top of glass and silicon substrates;

FIG. 6 is a field emission scanning electron microscope (FESEM) image of iridium films deposited from varying numbers of deposition cycles;

FIG. 7 is a graph illustrating the growth rate and resistivities of iridium films formed by ALD at different temperatures;

FIG. 8 illustrates atomic force microscope (AFM) topography images of various iridium and iridium oxide thin films deposited by ALD at various temperatures;

FIG. 9 illustrates AFM phase images of iridium thin films deposited by ALD at various temperatures;

FIG. 10 is a FESEM image of an Iridium film deposited by ALD on a trench patterned silicon substrate;

FIG. 11 is an x-ray diffractogram (XRD) of platinum films deposited by ALD with and without hydrogen pulses;

FIG. 12 is an x-ray diffractogram (XRD) of palladium films deposited by ALD with and without hydrogen pulses;

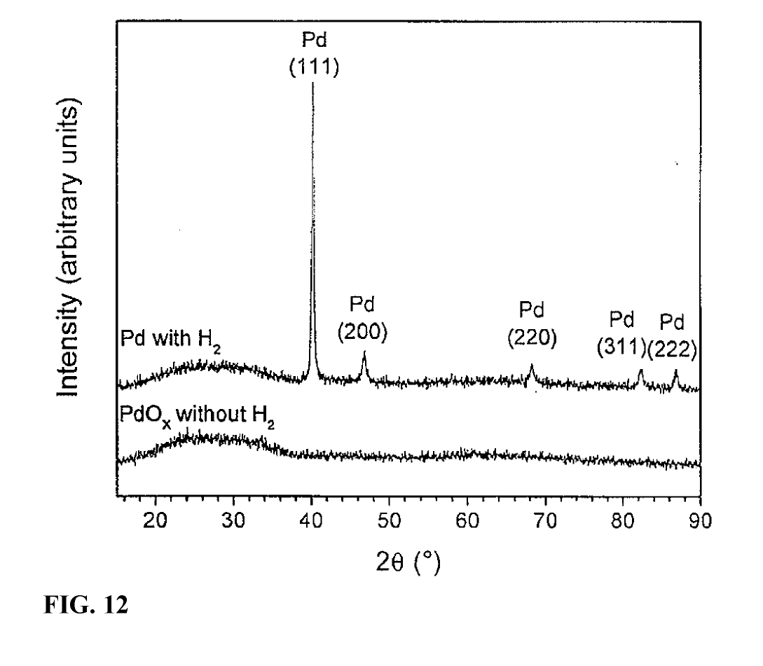

FIG. 13 is an x-ray diffractogram (XRD) of rhodium films deposited by ALD with hydrogen pulses;

### DETAILED DESCRIPTION OF THE PREFERRED EMBODIMENT

Noble metal thin films can be deposited on a substrate by atomic layer deposition (ALD) type processes. ALD type processes are based on controlled, self-limiting surface reactions of precursor chemicals. Gas phase reactions are avoided by feeding the precursors alternately and sequentially into the reaction chamber. Vapor phase reactants are separated from each other in the reaction chamber, for example, by removing excess reactants and/or reaction by-products from the reaction chamber between reactant pulses. Although reactants are separated and the process is based on self-limiting reactions, the skilled artisan will recognize that in some embodiments and/or some cycles, more than one monolayer may be deposited.

Briefly, a substrate is loaded into a reaction chamber and is heated to a suitable deposition temperature, generally at lowered pressure. Deposition temperatures are maintained below the thermal decomposition temperature of the reactants but at a high enough level to avoid condensation of reactants and to provide the activation energy for the desired surface reactions. Of course, the appropriate temperature window for any given ALD reaction will depend upon the surface termination and reactant species involved. Here, the temperature is preferably at or below about 200° C., as discussed in more detail below.

A first reactant comprising a noble metal is conducted or pulsed into the chamber in the form of a vapor phase pulse and contacted with the surface of the substrate. Conditions are preferably selected such that no more than about one monolayer of the first reactant is adsorbed on the substrate surface in a self-limiting manner. The appropriate pulsing times can be readily determined by the skilled artisan based on the particular circumstances. Excess first reactant and reaction byproducts, if any, are removed from the reaction chamber, such as by purging with an inert gas.

Purging the reaction chamber means that vapor phase precursors and/or vapor phase byproducts are removed from the reaction chamber such as by evacuating the chamber with a vacuum pump and/or by replacing the gas inside the reactor with an inert gas such as argon or nitrogen. Typical purging times are from about 0.05 to 20 seconds, more preferably between about 1 and 10, and still more preferably between about 1 and 2 seconds. However, other purge times can be utilized if necessary, such as where highly conformal step coverage over extremely high aspect ratio structures or other structures with complex surface morphology is needed. Also, batch ALD reactors can utilize longer purging times because of increased volume and surface area.

A second gaseous reactant comprising an oxidant is pulsed into the chamber where it reacts with the first reactant bound to the surface to form a noble metal oxide. Excess second reactant and gaseous byproducts of the surface reaction are removed from the reaction chamber, preferably by purging with the aid of an inert gas and/or evacuation.

A third gaseous reactant comprising a reducing agent is pulsed into the chamber where it reacts with the product of the first and second reactants on the substrate surface to reduce the noble metal oxide to noble metal. Excess third reactant and gaseous byproducts of the surface reaction are removed from the reaction chamber, preferably by purging with the aid of an inert gas and/or evacuation.

The steps of pulsing and purging are repeated until a thin noble metal film of the desired thickness has been formed on the substrate, with each cycle leaving typically less than or no more than a molecular monolayer.

As mentioned above, each pulse or phase of each cycle is preferably self-limiting. An excess of reactants is supplied in each phase to saturate the susceptible structure surfaces. Surface saturation ensures reactant occupation of all available reactive sites (subject, for example, to physical size or “steric hindrance” restraints) and thus ensures excellent step coverage.

According to a preferred embodiment, a noble metal thin film is formed on a substrate by an ALD type process comprising multiple deposition cycles, each noble metal deposition cycle comprising in order:

exposing the substrate to a pulse of a noble metal precursor to leave an adsorbed layer of the noble metal precursor; and

exposing the adsorbed layer of the noble metal precursor to a pulse of an reactive oxygen species to produce a noble metal oxide;

wherein the formed layer (typically less than a monolayer) of the noble metal oxide is exposed to a pulse of H₂ in the same chamber at the same temperature to reduce the noble metal oxide to noble metal.

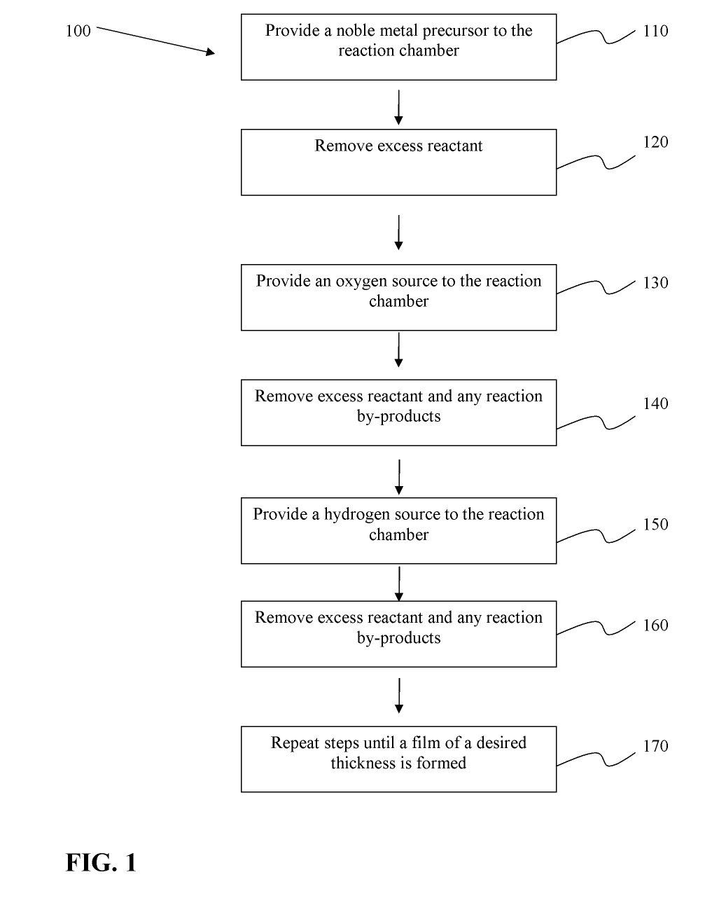

FIG. 1 is a flow chart generally illustrating a method for forming a noble metal thin film in accordance with some embodiments. According to a preferred embodiment, a noble metal thin film is formed on a substrate by an ALD type process 100 comprising multiple deposition cycles, each noble metal deposition cycle comprising in order:

providing a noble metal precursor 110 to the reaction chamber;

removing excess reactants 120;

providing an oxygen source 130 the reaction chamber;

removing excess reactant and any reaction by-products 140;

providing a hydrogen source 150; and

removing excess reactant and any reaction by-products 160

The deposition cycle can start with the provision of any reactant, provided that the noble metal is followed by an oxygen pulse and then a hydrogen pulse. Preferably, there are no intervening reactants provided between the noble metal pulse and the oxygen pulse and the oxygen pulse and hydrogen pulse.

The noble metal deposition cycle is typically repeated a predetermined number of times until a film of a desired thickness is formed 170. In some embodiments, multiple molecular layers of noble metal are formed by multiple deposition cycles. In other embodiments, a molecular layer or less of noble metal is formed.

Vapor phase precursors can be provided to the reaction space with the aid of an inert carrier gas. Removing excess reactants can include evacuating some of the contents of the reaction space or purging the reaction space with helium, nitrogen or any other inert gas. In some embodiments purging can comprise turning off the flow of the reactive gas while continuing to flow an inert carrier gas to the reaction space.

The substrate can comprise various types of materials. When manufacturing integrated circuits, the substrate typically comprises a number of thin films with varying chemical and physical properties. For example and without limitation, the substrate may comprise a dielectric layer, such as aluminum oxide, hafnium oxide, hafnium silicate, tantalum oxide, zirconium oxide, a metal, such as Ta, Ti, or W, a metal nitride, such as TaN, TiN, NbN, MoN or WN, silicon, silicon germanium, germanium or polysilicon. Further, the substrate surface may have been patterned and may comprise structures such as nodes, vias, trenches or microelectromechanical systems (MEMS).

The precursors employed in the ALD type processes may be solid, liquid or gaseous material under standard conditions (room temperature and atmospheric pressure), provided that the precursors are in vapor phase before being conducted into the reaction chamber and contacted with the substrate surface. “Pulsing” a vaporized precursor onto the substrate means that the precursor vapor is conducted into the chamber for a limited period of time. Typically, the pulsing time is from about 0.05 to 10 seconds. However, depending on the substrate type and its surface area, the pulsing time may be even higher than 10 seconds. Pulsing times can be on the order of minutes in some cases.

Preferably the metal precursor comprises a noble metal. Most preferably, the noble metal comprises Ir, Pd, Rh or Pt. In some embodiments the noble metal can be Ru.

Suitable noble metal precursors may be selected by the skilled artisan. In general, metal compounds where the metal is bound or coordinated to oxygen, nitrogen, carbon or a combination thereof are preferred. More preferably metallocene compounds, beta-diketonate compounds and acetamidinato compounds are used. In some embodiments a cyclopentadienyl precursor compound is used, preferably a bis(ethylcyclopentadienyl) compound. More preferably betadiketonate compounds are used. In some embodiments, X(acac)₃ or X(thd)_{y} compounds are used, where X is a noble metal, y is generally, but not necessarily between 2 and 3 and thd is 2, 2, 6, 6-tetramethyl-3, 5-heptanedionato and acac is 3, 5-pentanedionato. In some embodiments the noble metal precursors are organic compounds.

When depositing iridium thin films, preferred metal precursors may be selected from the group consisting of iridium betadiketonate compounds, iridium cyclopentadienyl compounds, iridium carbonyl compounds and combinations thereof. The iridium precursor may also comprise one or more halide ligands. In preferred embodiments, the precursor is Ir(thd)₃, (methylcyclopentadienyl)iridium(1, 3-cyclohexadiene) (MeCp)Ir(CHD) or tris(acetylacetonato)iridium(III) and derivates of those.

When depositing palladium films, preferred metal precursors include bis(hexafluoroacetylacetonate)palladium(II), Pd(acac)₂, and bis(2, 2, 6, 6-tetramethyl-3, 5-heptanedionato)palladium(II) and derivates of those.

When depositing platinum films, preferred metal precursors include (trimethyl)methylcyclopentadienylplatinum(IV), platinum(II)acetylacetonato, bis(2, 2, 6, 6-tetramethyl-3, 5-heptanedionato)platinum(II) and their derivatives.

When depositing rhodium films, preferred metal precursors include rhodium(III)acetylacetonato, cyclopentadienyl compounds of Rh and derivates of those.

When depositing ruthenium thin films, preferred metal precursors may be selected from the group consisting of bis(cyclopentadienyl)ruthenium, tris(2, 2, 6, 6-tetramethyl-3, 5-heptanedionato)ruthenium, 2, 4-(dimethylpentadienyl)(ethylcyclopentadienyl)ruthenium (Ru[(CH₃)₂C₅H₅)(EtCp)]) and tris(N, N′-diisopropylacetamidinato)ruthenium(III) and their derivatives, such as bis(N, N′-diisopropylacetamidinato)ruthenium(II) dicarbonyl, bis(ethylcyclopentadienyl)ruthenium, bis(pentamethylcyclopentadienyl)ruthenium and bis(2, 2, 6, 6-tetramethyl-3, 5-heptanedionato)(1, 5-cyclooctadiene)ruthenium(II). In preferred embodiments, the precursor is bis(ethylcyclopentadienyl) ruthenium (Ru[EtCp]₂).

Preferably, for a single wafer reactor, a noble metal precursor, such as a Ir, Pt, Rh or Pd precursor, is pulsed for from 0.05 to 10 seconds, more preferably for from 0.1 to 5 seconds and most preferably for about 0.3 to 3.0 seconds. Preferably, less than one monolayer of the noble metal precursor is adsorbed on the substrate.

The oxygen source may be an oxygen-containing gas pulse and can be a mixture of oxygen and inactive gas, such as nitrogen or argon. In some embodiments the oxygen source may be a molecular oxygen-containing gas pulse. In some embodiments the oxygen source comprises an activated or excited oxygen species. In some embodiments the oxygen source is atomic oxygen or oxygen radicals. In some embodiments the oxygen species is N₂O or an excited species of N₂O. In some embodiments the oxygen source comprises ozone. The oxygen source may be pure ozone or a mixture of ozone and another gas, for example an inactive gas such as nitrogen or argon. In other embodiments the oxygen source is oxygen plasma.

Preferably, the oxygen source is a reactive oxygen species. Preferably the reactive oxygen species comprises an oxygen species that is more reactive than molecular oxygen O₂. In some embodiments the reactive oxygen species comprises a species that can form atomic oxygen. The oxygen precursor pulse may be provided, for example, by pulsing ozone or a mixture of ozone and another gas into the reaction chamber. In other embodiments, ozone is formed inside the reactor, for example by conducting oxygen containing gas through an arc. In other embodiments an oxygen containing plasma is formed in the reactor. In some embodiments the plasma may be formed in situ on top of the substrate or in close proximity to the substrate. In other embodiments the plasma is formed upstream of the reaction chamber in a remote plasma generator and plasma products are directed to the reaction chamber to contact the substrate. As will be appreciated by the skilled artisan, in the case of remote plasma the pathway to the substrate can be optimized to maximize electrically neutral species and minimize ion survival before reaching the substrate.

The oxygen-containing precursor is preferably pulsed for from about 0.05 to 10 seconds, more preferably for from 0.1 to 5 seconds, most preferably for from about 0.2 to 3.0 seconds. In some embodiments, the oxygen pulse length is selected such that substantially all of the adsorbed noble metal species is oxidized.

In some embodiments, the hydrogen source is hydrogen (H₂). In some embodiments the hydrogen source is NH₃ or N₂H₄. In some embodiments the hydrogen source comprises compounds with chemical formulas comprising: NR^{I}R^{II}R^{III} or N₂R^{I}R^{II}, where R^{I}, R^{II} and R^{III} can independently selected to be hydrocarbons or hydrogen. In some embodiments the hydrogen source can be an excited species. Preferably, the hydrogen source is atomic hydrogen. A hydrogen source can be pulsed for from about 0.05 to 10 seconds. For single wafer reactors the hydrogen pulse length is preferably less than 10 seconds, more preferably less than 3 seconds, and most preferably less than 1 second. However, in some embodiments the pulse length can be more than 10 seconds, if preferred, preferably between about 10 to about 30 seconds. In some embodiments the hydrogen source is provided in each cycle.

Typically, the noble metal oxide formed from the pulse of the noble metal precursor and pulse of the oxygen source is less than a monolayer. Preferably, the hydrogen pulse length is selected such that it is long enough to reduce the noble metal oxide formed on the substrate. Preferably, substantially all of the noble metal oxide deposited by the noble metal and oxygen pulses is reduced to noble metal during the hydrogen pulse.

In some embodiments, more than a monolayer of noble metal oxide is formed and then reduced by the hydrogen source. A noble metal oxide cycle can include the provision of a noble metal reactant and oxygen containing precursor. For example, 1-5, 1-10, or 1-50 oxide cycles could be performed for each pulse of the hydrogen source. Preferably, the hydrogen pulse length is selected such that it is long enough to reduce the noble metal oxide formed on the substrate. Preferably, substantially all of the noble metal oxide deposited by the noble metal and oxygen pulses is reduced to noble metal during the hydrogen pulse.

In some embodiments, no other reactants are provided between the pulses of the oxygen-containing precursor and the hydrogen source.

One advantage of the deposition methods disclosed herein is that no separate annealing step is required to form a noble metal. A separate annealing step increases the processing time, increases manufacturing costs, may not be as efficient in reducing the noble metal oxide, and requires additional equipment. Separate annealing steps can require processing times on the order of an hour.

Preferably, each step of the ALD cycle is performed in the same deposition chamber and at the same temperature. In some embodiments the steps of the ALD deposition cycle are performed in-situ in the same reaction chamber.

The mass flow rate of the precursors can also be determined by the skilled artisan. In one embodiment, for deposition on 300 mm wafers the flow rate of metal precursors is preferably between about 1 and 1000 sccm without limitation, more preferably between about 100 and 500 sccm. The mass flow rate of the metal precursors is usually lower than the mass flow rate of the oxygen source, which is usually between about 10 and 10000 sccm without limitation, more preferably between about 100 -2000 sccm and most preferably between 100 -1000 sccm. Preferably the mass flow rate of the hydrogen is between about 1 and 1000 sccm without limitation, more preferably between about 10 and 500 sccm and most preferably between about 50 and 300 sccm.

The pressure in the reaction chamber is typically from about 0.01 and 20 mbar, more preferably from about 1 to about 10 mbar. However, in some cases the pressure will be higher or lower than this range, as can be readily determined by the skilled artisan.

Before starting the deposition of the film, the substrate is typically heated to a suitable growth temperature. Preferably, the substrate temperature and/or reaction chamber temperature is less than about 200° C. during deposition of the thin film, more preferably less than about 185° C. and even more preferably less than about 165° C. In some embodiments the substrate temperature can be less than 150° C., preferably less than 130° C., and more preferably less than 100° C. Preferably all of the deposition steps and cycles are performed in the same reaction space and at a constant temperature.

The preferred deposition temperature may vary depending on a number of factors such as, and without limitation, the reactant precursors, the pressure, flow rate, the arrangement of the reactor, and the composition of the substrate including the nature of the material to be deposited on. Typically, the minimum substrate temperature for deposition is around the evaporation temperature of the metal precursor. For example, when Ir(acac)₃ is used as the noble metal precursor the deposition temperature is about 165° C. as the evaporation temperature of Ir(acac)₃ is about 155° C. In some embodiments the substrate temperature during deposition can be lower than 100° C. The specific growth temperature may be selected by the skilled artisan using routine experimentation.

The deposition cycles can be repeated a predetermined number of times or until a desired thickness is reached. Preferably, the thin films are between about 2 nm and 200 nm thick.

The methods disclosed herein can be particularly useful for forming thin films on heat sensitive surfaces, such as plastics, biomaterials and polymers. In some cases the films can be used as conductors in different sensor applications.

In some embodiments the deposited noble metal thin film is conductive. In some embodiments, the resistivity of the deposited thin film is preferably less than 20 μΩcm and more preferably less than 15 μΩcm.

Further, the substrate surface may have been patterned and may comprise structures such as nodes, vias, trenches or microelectromechanical systems (MEMS). In some embodiments the noble metal thin film can be deposited on an adhesion layer, such as an oxide layer or aluminum oxide layer (see Example 1). In some embodiments the thin films are deposited on 3-D structures, such as MEMS or other structures with high aspect ratio trenches or vias. In some embodiments the step coverage is preferably greater than about 90% and even more preferably greater than about 95%.

The following non-limiting examples illustrate certain preferred embodiments of the invention. They were carried out in an F-120™ ALD reactor supplied by ASM Microchemistry Oy, Espoo.

### EXAMPLE 1

Iridium thin films were deposited from alternating and sequential pulses of tris(acetylacetonato)iridium(III), ozone, and hydrogen at temperatures between 165° C. and 200° C. Ir films were deposited on soda lime glass and silicon (111) substrates. During some tests an adhesion layer of Al₂O₃ was first deposited on the substrates by ALD using TMA and water. Ir(acac)₃ and ozone pulse lengths were 2 seconds. Hydrogen pulse lengths were 6 seconds. The purge length was 2 seconds. The flow rate of hydrogen was approximately 20 sccm. Nitrogen was used as a purge gas and the reaction space pressure was about 10 mbar. Ir(acac)₃ was supplied to the reactor by subliming the precursor at a temperature of about 155° C.

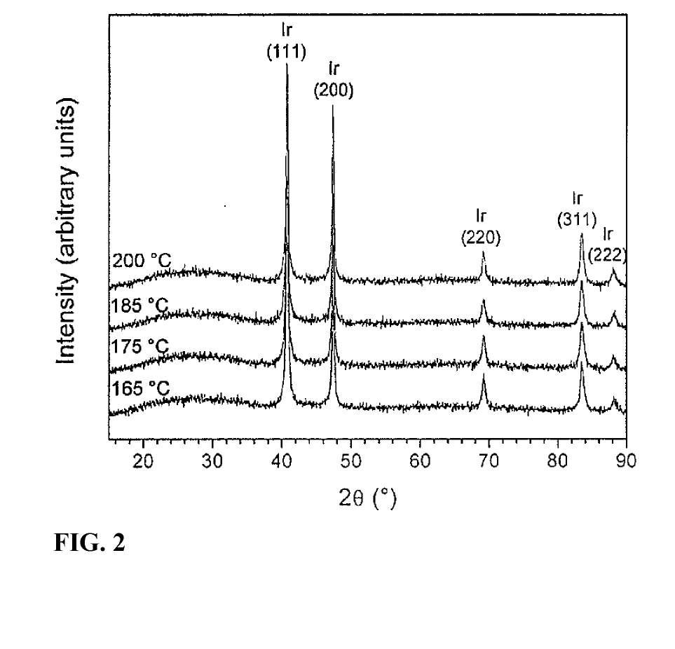

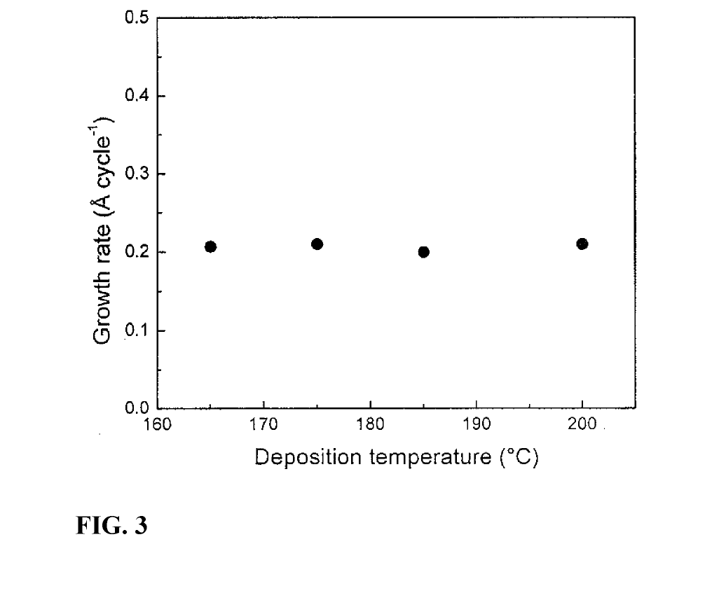

FIGS. 2-10 illustrate properties for iridium thin films deposited under various conditions. FIG. 2 is an x-ray diffractogram of iridium films formed from 3000 deposition cycles on soda lime glass with an aluminum oxide adhesion layer at various temperatures. All of the reflections shown in FIG. 2 indicate the presence of metallic iridium with no traces of iridium oxide. FIG. 3 illustrates growth rate versus temperature for iridium deposited using 3000 cycles on a silicon substrate with an Al₂O₃ layer on top. The growth rate was approximately the same for the various temperatures.

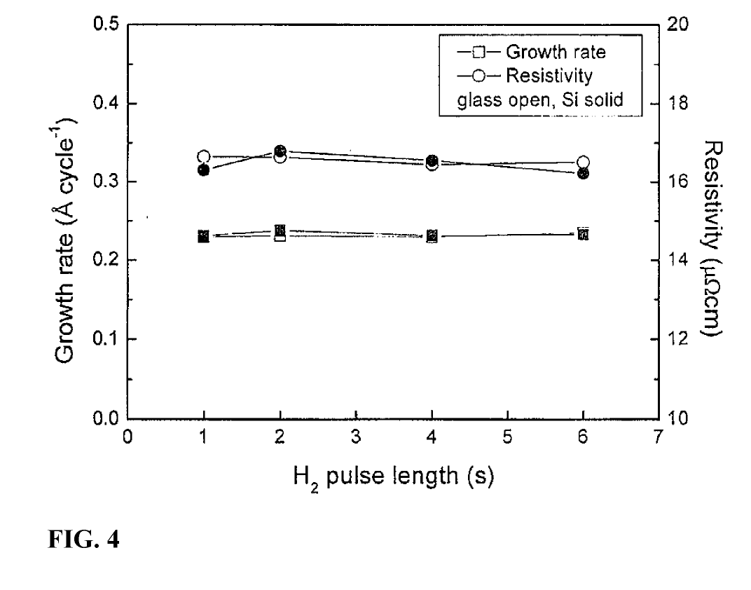

FIG. 4 compares the growth rate and resistivity of iridium films formed on silicon and soda lime glass substrates. An aluminum oxide adhesion layer was used along with 1 second pulses of ozone and Ir(acac)₃ while varying the hydrogen pulse length. FIG. 4 shows that similar Ir thin films were formed on both substrates.

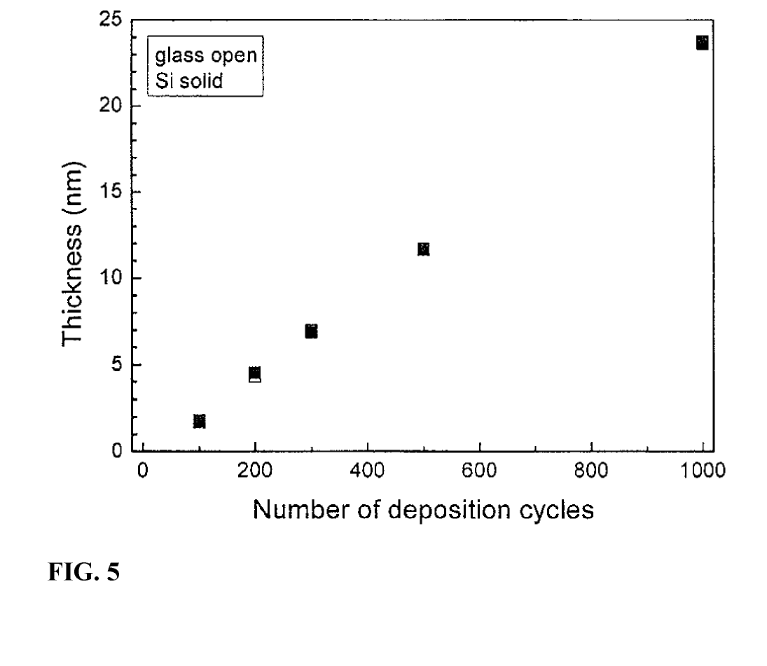

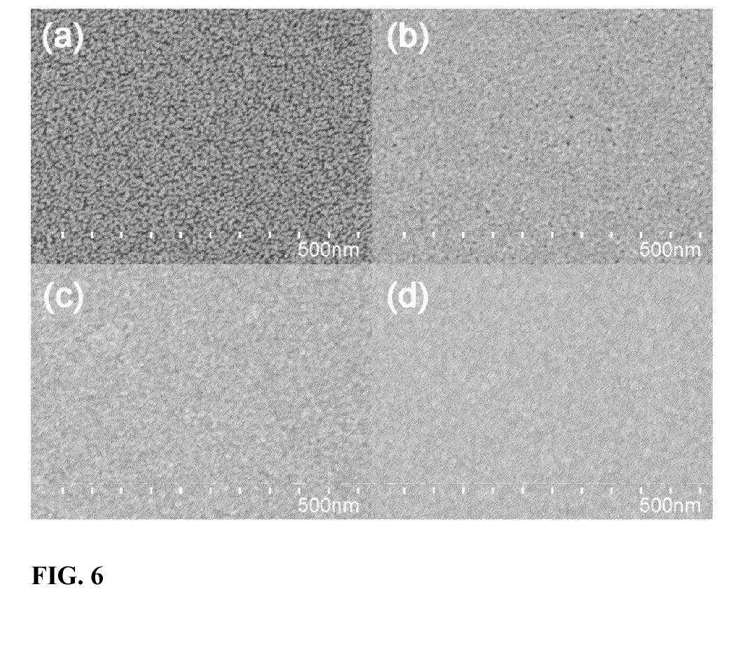

FIG. 5 compares the thickness of Ir films formed on soda lime glass and silicon substrates. An aluminum oxide adhesion layer was used as a starting surface. Pulse lengths for all precursors were 2 seconds. The Ir growth rate was similar on both substrate types. FIG. 6 shows FESEM images of Ir films deposited at 185° C. using 100, 200, 300, and 500 cycles for (a)-(d), respectively. The films were formed using the same conditions as FIG. 5. The samples shown for (a) and (b) show tiny holes indicating that the film is not yet continuous. Samples (c) and (d) both appear to be continuous from the FESEM data.

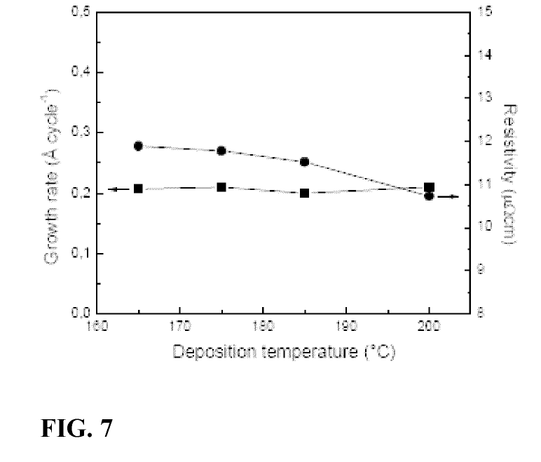

FIG. 7 illustrates the growth rate and resistivity of Ir films formed on a silicon substrate with an aluminum oxide adhesion layer. The pulse lengths were 2 seconds for Ir(acac)₃ and ozone and 6 seconds for hydrogen. The resistivity values decreased slightly with increasing temperature. The growth rate was approximately constant over the illustrated temperature range, around 0.20 Å per cycle. For comparison purposes the resistivities of 40 nm IrO₂ films were more than ten times higher than the resistivities measured for Ir films deposited at corresponding temperatures.

TABLE 1
Elemental compositions (TOF-ERDA) and surface roughness
(AFM) of the Ir films deposited between 165 and 200 ° C.

| dep. temp. | thickness (EDX) | roughness (AFM) | H | C | O* | Ir |
|---|---|---|---|---|---|---|
| (° C.) | (nm) | (nm) | (at %) | (at %) | (at %) | (at %) |
| 165 | 64 | 1.1 | 1.8 ± 0.3 | 0.6 ± 0.1 | 3.6 ± 0.3 | 94 ± 1 |
| 175 | 65 | 1.3 | 1.6 ± 0.3 | 0.4 ± 0.1 | 7.0 ± 0.3 | 91 ± 1 |
| 185 | 62 | 1.4 | 1.9 ± 0.3 | 0.3 ± 0.1 | 3.7 ± 0.2 | 94 ± 1 |
| 200 | 64 | 1.1 | 1.2 ± 0.2 | 0.5 ± 0.1 | 6.3 ± 0.3 | 92 ± 1 |

Table 1 illustrates physical and chemical data for Ir films deposited on silicon with an aluminum oxide adhesion layer. The films exhibited hydrogen impurities below about 2% and carbon impurities below 1%. The Ir films had oxygen impurities from about 4% to about 7%.

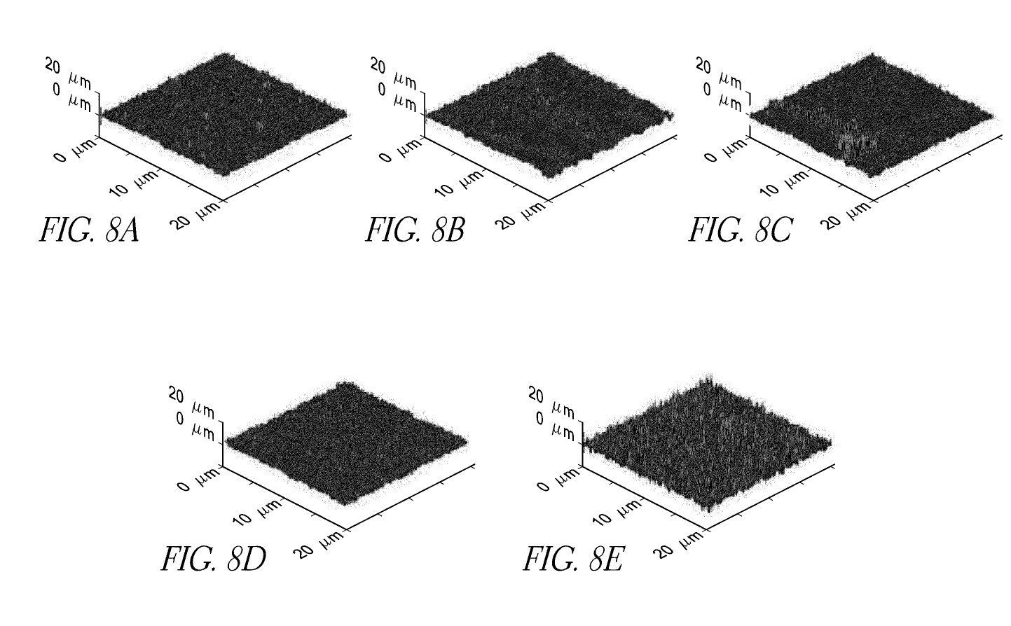

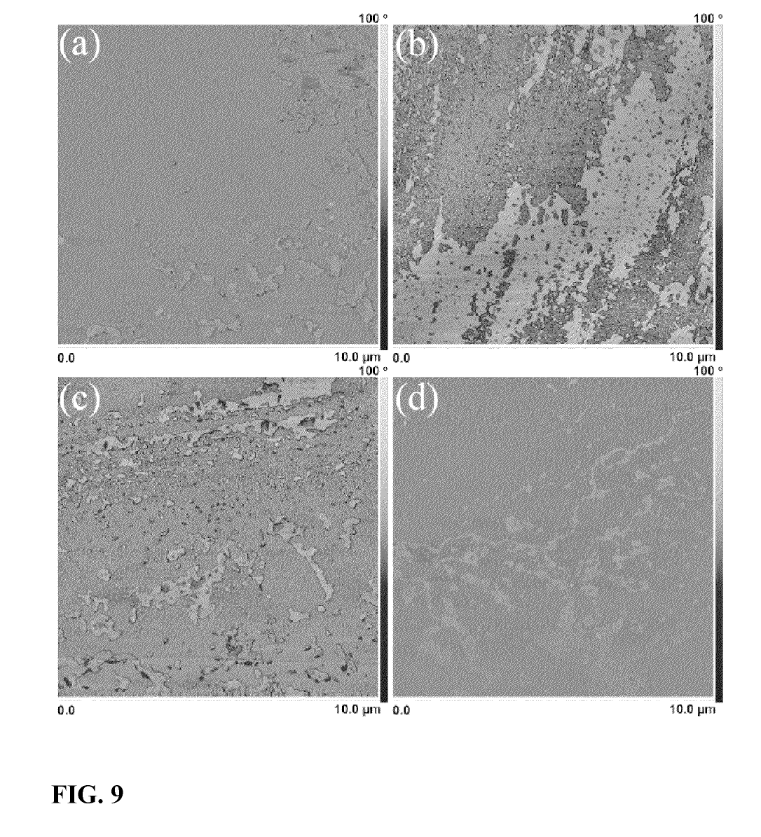

FIG. 8 illustrates AFM topography images of 60 nm thick Ir films deposited at 165° C. (a), 175° C. (b), 185° C. (c), and 200° C. (d). A 40 nm thick film of IrO₂ is illustrated in (e) for comparison purposes. The surface roughness varied between 1.1 and 1.4 nm for the Ir films. The surface roughness for of O₂ was approximately 2.2 nm. FIG. 9 illustrates additional AFM phase images of the samples from FIG. 8.

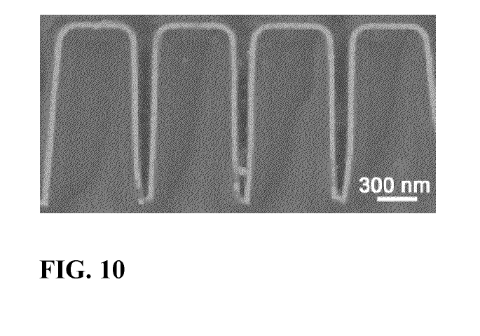

FIG. 10 illustrates FESEM of an Ir film deposited by ALD on a trench structure on a silicon substrate at 165° C. by 2500 deposition cycles. A pulse length of 5 seconds was used for all precursors. FIG. 10 shows that the deposited film had good conformality. The appearance of defects at the bottom of the sample are related to the preparation of the cross-section sample as the sample was simply made by breaking the substrate with no additional polishing.

All of the iridium samples showed good adhesion properties, passing the tape test regardless of the substrate material and with and without the use of an adhesion layer.

Tests were also performed using methanol as a reducing agent instead of H₂ but they did not produce high quality Ir films.

### EXAMPLE 2

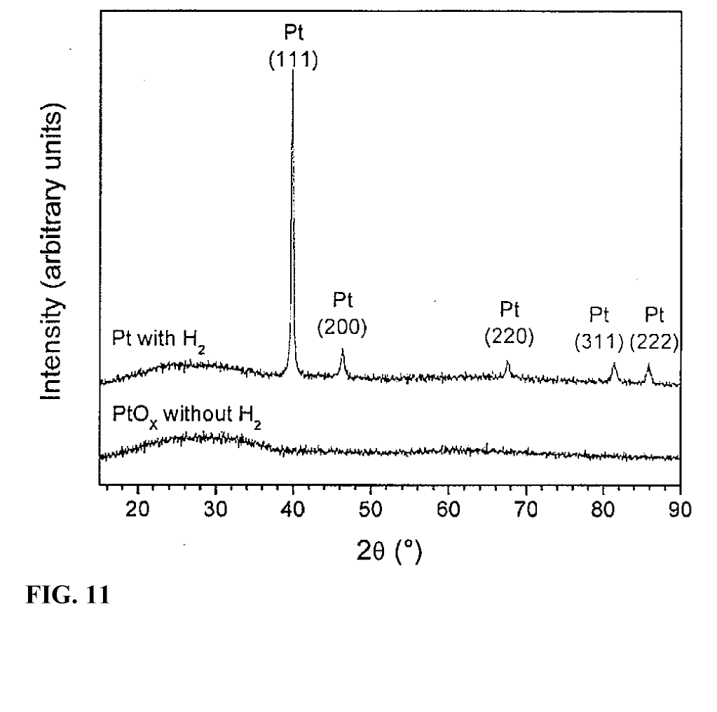

Platinum thin films were formed using alternating and sequential pulses of Pt(acac)₂, ozone, and hydrogen. Platinum films were deposited using 1000 deposition cycles with 4 second pulses of Pt(acac)₂, 2 second pulses of ozone, and 6 second pulses of hydrogen. A purge length of 2 seconds was used between pulses. The Pt films were deposited on a soda lime glass substrate with an aluminum oxide adhesion layer. FIG. 11 illustrates XRD patterns for Pt and platinum oxide films formed at a substrate temperature of 130° C. The XRD patterns show the presence of metallic reflections from the film formed with hydrogen pulses in contrast to the platinum oxide film, which does not show metallic reflections.

### EXAMPLE 3

Palladium thin films were formed using alternating and sequential pulses of Pd(thd)₂, ozone, and hydrogen. Palladium films were deposited using 1000 deposition cycles. The Pd film was deposited using 1 second pulses of Pt(acac)₂, 2 second pulses of ozone, and 2 second pulses of hydrogen. The purge length after the noble metal precursor was 1 second with 2 second purges after the other precursors. The PdOₓ film was formed using one second pulses and purges. The Pd films were deposited on a soda lime glass substrate. FIG. 11 illustrates XRD patterns for Pd and PdOₓ films formed at a substrate temperature of 170° C. The XRD patterns show the presence of metallic reflections for the film formed with hydrogen pulses in contrast to the PdOₓ film, which does not show metallic reflections.

### EXAMPLE 4

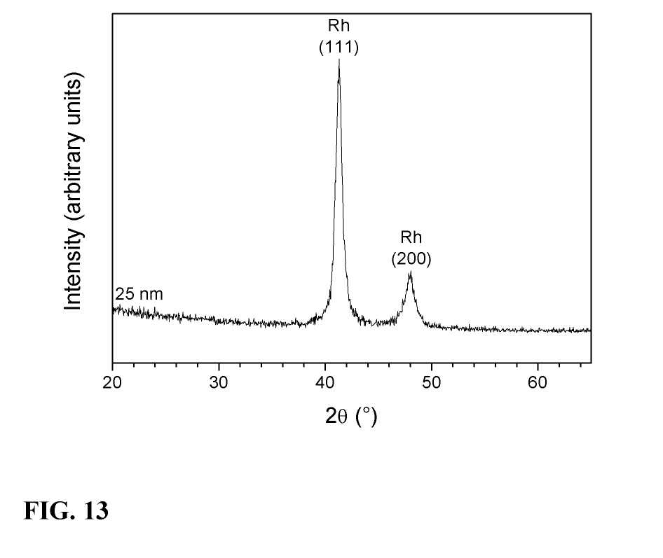

Rhodium thin films were formed using alternating and sequential pulses of Rh(acac)₃, ozone, and hydrogen on a silicon substrate. Rhodium films were deposited using 1000 deposition cycles with 3 second pulses of Rh(acac)₃, 3 second pulses of ozone, and 6 second pulses of hydrogen. A purge length of 3 seconds was used between pulses. FIG. 13 illustrates XRD patterns for Pt and platinum oxide films formed at a substrate temperature of 160° C. The XRD patterns show the presence of metallic rhodium reflections from the film formed with hydrogen pulses.

It will be appreciated by those skilled in the art that various modifications and changes can be made without departing from the scope of the invention. Similar other modifications and changes are intended to fall within the scope of the invention, as defined by the appended claims.

We claim:

1. A method of depositing a noble metal film on a substrate in a reaction chamber by atomic layer deposition, the method comprising:
conducting a plurality of ALD cycles, each of the cycles forming less than a complete monolayer of noble metal oxide, each of the cycles comprising:
exposing the substrate to a pulse of a noble metal precursor to leave an adsorbed layer of the noble metal precursor,
exposing the adsorbed layer of the noble metal precursor to a pulse of an reactive oxygen species to produce a noble metal oxide, and
wherein the noble metal oxide is exposed to a pulse of H₂ in the same chamber at the same temperature to reduce the noble metal oxide to noble metal, wherein the substrate temperature during the ALD cycle is less than about 200° C.

2. The method of claim 1, wherein the reactive oxygen species comprises O₃, N₂O, O-atoms, O-radicals, or O-plasma.

3. The method of claim 1, wherein the noble metal comprises Ir, Pd, Rh or Pt.

4. The method of claim 1, wherein the substrate temperature during the ALD cycle is less than 185° C.

5. The method of claim 1, wherein the substrate temperature during the ALD cycle is less than 165° C.

6. The method of claim 1, wherein the substrate temperature during the ALD cycle is less than 150° C.

7. The method of claim 1, wherein the substrate temperature during the ALD cycle is less than 130° C.

8. The method of claim 1, wherein the substrate temperature during the ALD cycle is less than 100° C.

9. The method of claim 1, wherein the length of the hydrogen pulse is less than about 10 seconds.

10. The method of claim 1, wherein the length of the hydrogen pulse is less than about 3 seconds.

11. The method of claim 1, wherein the length of the hydrogen pulse is less than about 1 second.

12. The method of claim 1, wherein the deposited noble metal has a resistivity less than about 20 μΩcm.

13. The method of claim 1, wherein the deposited noble metal has a resistivity less than about 15 μΩcm.

14. The method of claim 1, wherein the deposited noble metal is deposited without a separate annealing step.

15. The method of claim 1, wherein the noble metal film is deposited on a substrate with three-dimensional features.

16. The method of claim 15, wherein the noble metal film has a step coverage of greater than about 90%.

17. The method of claim 15, wherein the deposited noble metal has a step coverage of greater than about 95%.

18. An atomic layer deposition (ALD) process for forming a noble metal thin film comprising alternately and sequentially contacting a substrate in a reaction space, in order, with a noble metal precursor, a reactive oxygen source, and a hydrogen source, wherein the substrate temperature during deposition is less than about 200° C., and wherein contacting the substrate with a hydrogen source comprises pulsing the hydrogen source to the reaction space for a duration of 10 seconds or less.

19. The method of claim 18, wherein the contacting steps are separated by purge steps.

20. The method of claim 18, wherein the noble metal comprises Ir, Pd, Rh or Pt.

21. The method of claim 18, wherein the reactive oxygen source comprises O₃, O-atoms, N₂O, O-radicals, and O-plasma.

22. The method of claim 18, wherein the contacting in the ALD process is performed in-situ.
